(19) United States
(12) Patent Application Publication
(10) Pub. No.: US 2024/0395449 A1
(43) Pub. Date: Nov. 28, 2024

(54) ENCLOSURE FOR MITIGATING RF POWER RAMP UP IN ICP SOURCE

(71) Applicant: LAM RESEARCH CORPORATION, Fremont, CA (US)

(72) Inventor: Anurag Kumar MISHRA, Fremont, CA (US)

(21) Appl. No.: 18/691,636

(22) PCT Filed: Sep. 14, 2022
(86) PCT No.: PCT/US2022/043422

§ 371 Date: Mar. 13, 2024

Related U.S. Application Data
(60) Provisional application No. 63/246,133, filed on Sep. 20, 2021.

(51) Int. Cl. H01F 27/02

(52) U.S. Cl. CPC H01F 27/02

(57) ABSTRACT

An enclosure for a coil in a substrate processing system includes a first body comprised of a dielectric material. The first body includes a first surface, a second surface, a first edge, and a second edge, and the first surface defines an interior volume of the enclosure configured to contain the coil. At least one feature defined in the first surface of the first body includes an opening that has a first width, sidewalls extending from the first surface in a direction toward the second surface, and a back wall located radially outward of the first surface. The sidewalls extend from the first surface to the back wall, and a second distance between the sidewalls varies as the at least one feature extends in a radially outward direction from the opening.

### CROSS-REFERENCE TO RELATED APPLICATIONS

This application claims the benefit of U.S. Provisional Application No. 63/246,133, filed on Sep. 20, 2021. The entire disclosure of the application referenced above is incorporated herein by reference.

### FIELD

The present disclosure relates to enclosures for inductively coupled plasma (ICP) sources in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to perform treatments on substrates such as semiconductor wafers. Examples of the treatments include deposition, etching, cleaning, etc. The substrate processing systems typically include a processing chamber including a substrate support, a gas delivery system and a plasma generator.

During processing, the substrate is arranged on the substrate support. Different gas mixtures may be introduced by the gas delivery system into the processing chamber. In some applications, radio frequency (RF) plasma such as inductively coupled plasma (ICP) may be used to activate chemical reactions (e.g., to etch the substrate). ICP systems generate plasma by supplying RF plasma power to coils arranged outside of a processing chamber adjacent to a dielectric window. Process gas mixtures flowing inside the processing chamber are ignited by magnetic fields to create plasma.

### SUMMARY

An enclosure for a coil in a substrate processing system includes a first body comprised of a dielectric material. The first body includes a first surface, a second surface, a first edge, and a second edge, and the first surface defines an interior volume of the enclosure configured to contain the coil. At least one feature defined in the first surface of the first body includes an opening that has a first width, sidewalls extending from the first surface in a direction toward the second surface, and a back wall located radially outward of the first surface. The sidewalls extend from the first surface to the back wall, and a second distance between the sidewalls varies as the at least one feature extends in a radially outward direction from the opening.

In other features, the back wall has a second width greater than the first width. The at least one feature includes a first portion and a second portion, the first portion includes a slot defined in the first surface, and the second portion is located radially outward of the first portion and comprises the back wall. An outer perimeter of the first portion and the second portion in a plan view is “T”-shaped. An outer perimeter of the first portion and the second portion in a plan view is “L”-shaped. A shape of the at least one feature in a plan view is one of triangular and trapezoidal.

In other features, the enclosure further includes a second body arranged radially outward of the first body. The at least one feature comprises a first portion and a second portion, the first portion is formed in the first body, and the second portion is formed in the second body. The first portion includes a slot defined in the first surface, the second portion is located radially outward of the first portion and includes the back wall, and the back wall has a second width greater than the first width. The enclosure is comprised of quartz. The at least one feature comprises a plurality of the features. The first body is cylindrical. A system includes the enclosure and further includes a coil arranged within the enclosure.

An enclosure for a coil in a substrate processing system includes a body comprised of a dielectric material. The body includes a first surface, a second surface located radially outward of the first surface, a first edge, and a second edge. A first feature is defined in the first surface of the body. At least one second featured is defined in the first surface of the body. Each of the first feature and the at least one feature includes a first portion that defines an opening in the first surface and has a first width and a second portion located radially outward of the first portion. The second portion defines a recess that has a second width greater than the first width.

In other features, sidewalls extend from the first surface to a back wall of the second portion and the back wall has the second width. The first portion and the second portion define an outer perimeter that is “T”-shaped in a plan view. The first portion comprises a rectangular slot that extends between the first edge and the second edge on the first surface. The dielectric material is quartz. The body is cylindrical.

An enclosure for a coil in a substrate processing system includes a body comprised of a dielectric material. The body includes a first surface, a second surface located radially outward of the first surface, a first edge, and a second edge. A plurality of features is defined in the first surface of the body. Each of the plurality of features includes a first portion that includes a slot that defines an opening in the first surface that extends from the first edge to the second edge. The first portion has a first width. A second portion is located radially outward of the first portion, the second portion defines a recess that includes a back wall located radially outward of the first surface and radially inward of the second surface, and the back wall has a second width greater than the first width.

In other features, the plurality of features is uniformly spaced in a circumferential direction around the first surface. The body is cylindrical.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of an example substrate processing system according to the present disclosure;

FIG. 1B is a plan view of an enclosure for a coil of the substrate processing system of FIG. 1A;

FIG. 2A is an isometric view of an enclosure according to the present disclosure;

FIG. 2B is a plan view of an enclosure of FIG. 2A;

FIGS. 2C and 2D show a portion of the enclosure of FIGS. 2A and 2B including feature according to the present disclosure;

FIGS. 3A and 3B are plan views of examples of another enclosure for a coil according to the present disclosure; and

FIGS. 4A, 4B, 4C, 4D, and 4E are examples of features of enclosures according to the present disclosure.

In the drawings, reference numbers may be reused to identify similar and/or identical elements.

### DETAILED DESCRIPTION

Some substrate processing systems are configured to generate inductively coupled plasma (ICP) within a processing chamber. For example, an RF drive system energizes an ICP source (e.g., inductive coils) arranged above a dielectric window to generate ICP within the processing chamber. An enclosure (e.g., a quartz enclosure including one or more concentric rings) surrounds the ICP source.

Over time, processing byproducts such as metal and other materials are deposited on a first (e.g., inner) sidewall surface of the enclosure. Build-up of conductive materials enables eddy currents to flow around the first surface of the enclosure and the enclosure may function as a Faraday shield between the ICP source and a plasma body. As a number of RF hours increases, deposition of material onto the enclosure also increases, causing a corresponding increase in eddy current magnitude and a decrease in an amount of power delivered to the plasma body. Accordingly, to maintain a desired beam current, RF power must be increased to compensate for material deposition on the enclosure. Further, a mean time between cleaning (MTBC) is decreased (i.e., components of the substrate processing system may require more frequent cleaning).

In some examples, the inner surface of the enclosure may include features configured to mitigate the effects of material build-up. In one example, the first surface includes a plurality of vertical slots. The slots interrupt continuous build-up of material in a circumferential direction around first surface of the enclosure. However, over time, material is deposited on interior surfaces of the slots and eventually forms a continuous path of material to allow the flow of eddy currents.

An enclosure for an ICP source according to the present disclosure includes one or more features configured to prevent formation of a continuous path of conductive material around the first surface of the enclosure. For example, the features may include a slot or opening defined in the first surface of the enclosure. As the slots extend into the enclosure (e.g., in a radially outward direction), a width of the slots (e.g., a distance between sidewalls of the slots) increases such that the sidewalls do not extend directly to a back wall of the slots. In other words, a path from the first surface of the enclosure, through the slots, and to the back wall of the slots is interrupted and material is not able to form a continuous conductive path.

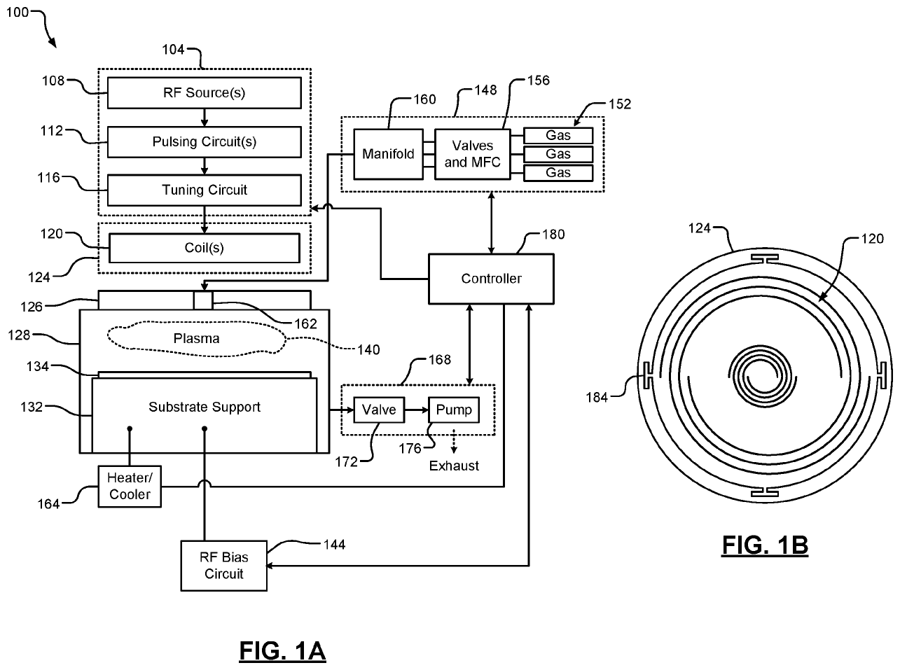

Referring now to FIGS. 1A and 1B, an example of a substrate processing system 100 according to the present disclosure is shown. The substrate processing system 100 includes a coil driving circuit 104. In some examples, the coil driving circuit 104 includes an RF source 108, a pulsing circuit 112, and a tuning circuit 116. The pulsing circuit 112 controls a TCP envelope of the RF signal and varies a duty cycle of TCP envelope (e.g., between 1% and 99%) during operation. As can be appreciated, the pulsing circuit 112 and the RF source 108 can be combined or separate.

The tuning circuit 116 may be directly connected to one or more inductive coils 120. The tuning circuit 116 tunes an output of the RF source 108 to a desired frequency and/or a desired phase, matches an impedance of the coils 120 and/or splits power between the coils 120. While examples including multiple coils are shown, a single coil including a single conductor or multiple conductors can be used. In some examples, the coils 120 are arranged in an enclosure (e.g., a coil enclosure) 124.

A dielectric window 126 is arranged along one side of a processing chamber 128. The processing chamber 128 further comprises a substrate support (or pedestal) 132 to support a substrate 134. The substrate support 132 may include an electrostatic chuck (ESC), a mechanical chuck, or other type of chuck. Process gas is supplied to the processing chamber 128 and plasma 140 is generated inside of the processing chamber 128. An RF bias or drive circuit 144 may be used to supply an RF bias to the substrate support 132 during operation to control ion energy. The RF bias drive circuit 144 may include an RF source and an impedance matching circuit (not shown).

A gas delivery system 148 may be used to supply a process gas mixture to the processing chamber 128. The gas delivery system 148 may include gas sources 152 (e.g. precursor, vapor, one or more other gases, inert gases), a gas metering system 156 such as valves and mass flow controllers, and a manifold 160. A gas injector 162 may be arranged at a center of the dielectric window 126 (or other location) and is used to inject gas mixtures from the gas delivery system 148 into the processing chamber 128.

A heater/cooler 164 may be used to heat/cool the substrate support 132 to a predetermined temperature. An exhaust system 168 includes a valve 172 and pump 176 to control pressure in the processing chamber and/or to remove reactants from the processing chamber 128 by purging or evacuation.

A controller 180 may be configured to control various components and processes of the substrate processing system 100. For example, the controller 180 monitors system parameters and controls delivery of the gas mixtures, striking, maintaining and extinguishing the plasma, removal of reactants, supply of cooling gas, etc.

An example arrangement of the coils 120 within the enclosure 124 according to the present disclosure is shown in a plan (i.e., top down) view in FIG. 1B. The enclosure 124 includes one or more features 184 configured to prevent formation of a continuous path of conductive material around a first (e.g., inner) surface of the enclosure 124 as described below in more detail.

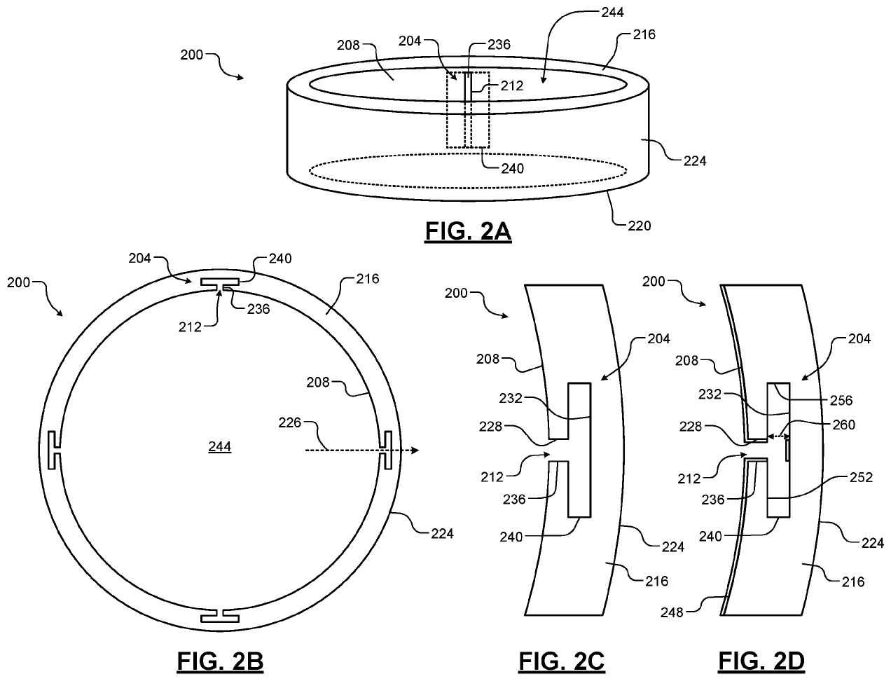

FIGS. 2A, 2B, 2C, and 2D show an example enclosure 200 for an ICP source according to the present disclosure. For example, the enclosure 200 is comprised of quartz or another dielectric material. The enclosure 200 includes one or more features 204 configured to prevent formation of a continuous path of conductive material around a first (e.g., inner) surface 208 of the enclosure 200. Although shown having a ring or cylindrical shape, in other examples the enclosure 200 may have other shapes (e.g., square, rectangular, elliptical, etc. FIG. 2A is an isometric view of the enclosure 200. FIG. 2B is a plan (i.e., top down) view of the enclosure 200. FIGS. 2C and 2D show a portion of the enclosure 200 including one of the features 204.

The features 204 each comprise a slot (e.g., a linear, vertical slot) 212 defined in the first surface 208 of the enclosure 200. Although, as shown, an opening of the slot 212 is rectangular, in other examples the slot 212 may have other shapes. The slot 212 may extend only partially between a first (e.g., upper) rim or edge 216 and a second (e.g., lower) rim or edge 220 of the enclosure 200, as shown. In other examples, the slot 212 may extend completely from the first edge 216 to the second edge 220 of the enclosure 200.

As the slots 212 extends into a body 224 of the enclosure 220 (e.g., in a radially outward direction indicated by arrows 226), a width of the slots 212 (e.g., a distance between sidewalls 228 of the slots 212) increases such that the sidewalls 228 do not extend directly to a back (e.g., radially outer) wall 232 of the slots 212. In other words, a path from the first surface 208 of the enclosure 200, through the slots 212, and to the back wall 232 of the slots 212 is interrupted such material is not able to form a continuous conductive path in a circumferential direction around the first surface 208.

As shown in more detail in FIGS. 2C and 2D, the slots 212 comprise a first portion 236 and a second portion 240 located radially outward of the first portion 236. The first portion 236 corresponds to the vertically-extending rectangle defined in the first surface 208 as shown in FIG. 2A. In other words, the first portion 236 of the slot 212 corresponds to a portion of the slot 212 that faces and opens into an interior volume 244 of the enclosure 220. The first portion 236 has a first width.

The second portion 240 corresponds to a groove or recess and has a second width greater than the first width. In other words, the second width of the second portion 240 extends further than the first width of the first portion 236 in a direction perpendicular to the radial direction indicated by the arrows 226 (i.e., in a circumferential or azimuthal direction). As shown, the first portion 236 and the second portion 240 together define a “T”-shaped outer perimeter of the slot 212 in a plan view.

FIG. 2C shows the first surface 208 and slot 212 prior to any material being deposited onto surfaces of the enclosure 200 (or subsequent to cleaning the enclosure 200). Conversely, FIG. 2D shows accumulation of material 248 onto the first surface 208, sidewalls 228 of the slot 212, and a back wall 232 of the slot 212. For example, the material 248 comprises processing byproducts such as metal and other materials. The material 248 may be conductive. However, since the second width of the second portion 240 is greater than the first width of the first portion 236, the material 248 is not deposited on a radially inner wall 252 and sidewalls 256 of the second portion 240. Instead, the material 248 is only deposited on a portion of the back wall 232 that is aligned with (i.e., exposed to) the opening defined by the first portion 236.

In other words, a path from the first surface 208 along the sidewalls 228 of the first portion 236 is interrupted by a gap 260 defined by the second portion 240 and is not in contact with the back wall 232 of the slot 212. Accordingly, the material 248 accumulated on the first surface 208 and the sidewalls 228 is not in direct (i.e., electrical) contact with the material 248 accumulated on the back wall 232 of the slot 212. Consequently, a conductive path of the material 248 on the first surface 208 of the enclosure 200 is interrupted by the slot 212.

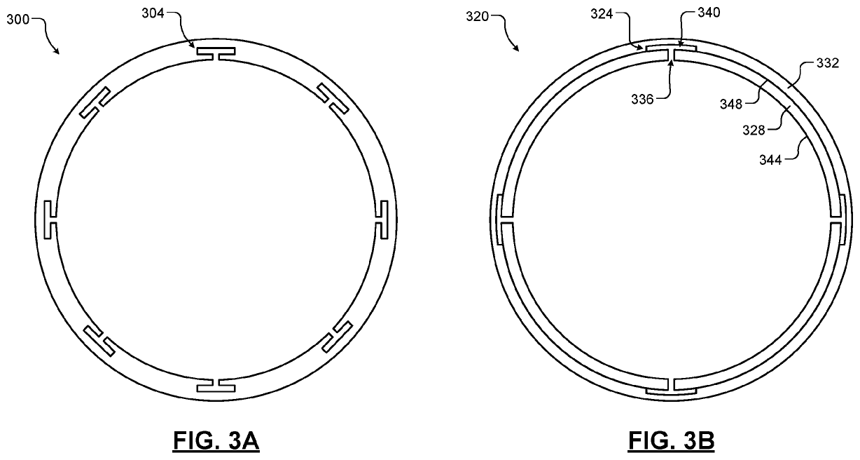

Referring now to FIG. 3A, another example enclosure 300 according to the present disclosure is shown in a plan view. The enclosure 300 includes a plurality of features 304 configured to prevent formation of a continuous path of conductive material within the enclosure 300 as described above in FIGS. 2A-2D. In this example, the enclosure 300 includes eight of the features. In other words, although FIG. 2B shows the enclosure 200 comprising four of the features 204, in other examples the enclosure 200 may comprise fewer (e.g., one, two, or three) or more than four of the features 204. The features 304 may be uniformly spaced in an azimuthal or circumferential direction (as shown) or non-uniformly spaced.

Referring now to FIG. 3B, another example enclosure 320 according to the present disclosure is shown in a plan view. The enclosure 320 includes a plurality of features 324 configured to prevent formation of a continuous path of conductive material within the enclosure 320 as described above in FIGS. 2A-2D and 3A. As described in FIGS. 1, 2A-2D, and 3, the enclosures 124, 200, and 300 are comprised of a single body or ring (e.g., the body 224 shown in FIG. 2A). Conversely, the enclosure 320 of FIG. 3B is comprised of a first (e.g., inner) ring or body 328 and a second (e.g., outer) ring or body 332. The first body 328 and the second body 332 may be comprised of same or different materials (e.g., quartz or another dielectric material).

A first portion 336 of each of the features 324 is defined in the first body 328. A second portion 340 of each of the features 324 is defined in the second body 332. For example, the first portion 336 is comprised of a vertically-extending slot defined in a first (e.g., radially inner) surface 348 of the first body 328 of the enclosure 320. In other words, the first portion 336 may be analogous to the first portion 236 of FIGS. 2C and 2D. The first portion 336 has a first width.

Conversely, the second portion 340 is comprised of a recess defined in a first (e.g., radially inner) surface 348 of the second body 332 of the enclosure 320. In other words, the second portion 340 may be analogous to the second portion 240 of FIGS. 2C and 2D. The second portion 340 has a second width greater than the first width in a circumferential or azimuthal direction. In a plan view, a perimeter defined by the first portion 336 and the second portion 340 is generally “T”-shaped. While the second portion 240 shown in FIGS. 2A-2D is generally straight (i.e., not curved), the second portion 340 as shown in FIG. 3B may be curved to coincide with a curvature of the radially inner surface 348 of the second body 332.

The configuration shown in FIG. 3B may facilitate manufacture and assembly of the enclosure 320. For example, when comprised of a single body such as the body 224 shown in FIG. 2A, forming the features 204 in the enclosure 200 (e.g., various processes such as machining, etching, molding, etc.) may be difficult. Conversely, as shown in FIG. 3B, the first portion 336 defined in the first body 328 can be formed separately from the second portion 340 defined in the second body 332. For example, slots corresponding to the first portion 336 may simply be machined or otherwise formed in the first body 328. Similarly, recesses corresponding to the second portion 340 may be machined or otherwise formed in the second body 332.

Subsequent to forming the first portion 336 in the first body 328 and the second portion 340 in the second body 332, the first body 328 and the second body 332 may be assembled together to form the enclosure 320. For example, the first body 328 is nested within the second body 332. In some examples, the second body 332 is fixedly attached to the first body 328 (e.g., using an adhesive, mechanical fasteners, etc.). In other examples, the second body 332 is not attached to is removably attached to the first body 328 (e.g., using removable mechanical fasteners such as screws). Accordingly, the first body 328 and the second body 332 may be separately removed for cleaning or other maintenance. Further, one of the first body 328 and the second body 332 may be removed, repaired, replaced, etc. without needing to remove or replace the other of the first body 328 and the second body 332.

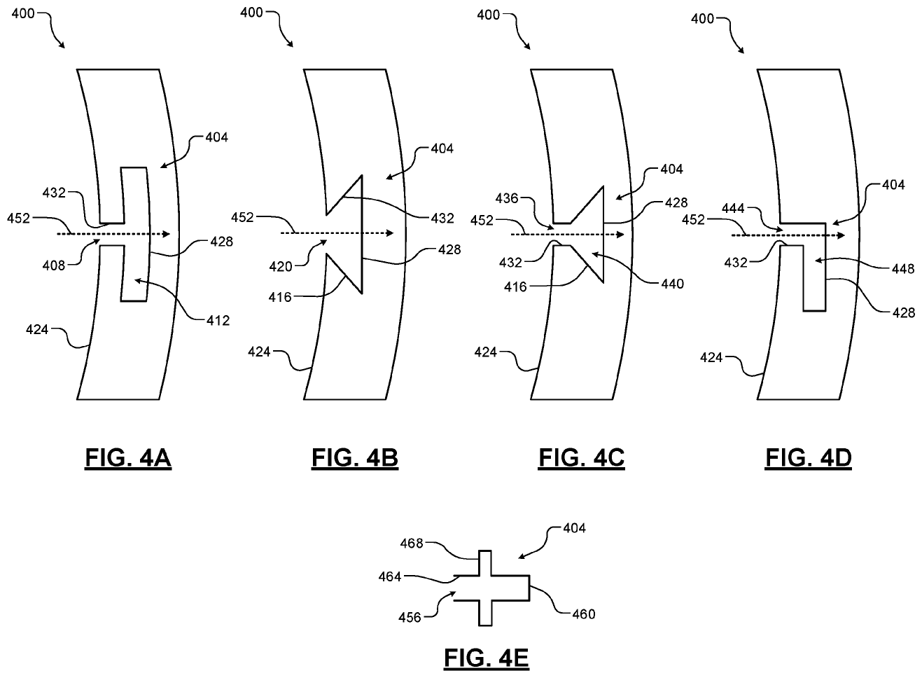

Referring to FIGS. 4A, 4B, 4C, and 4D, plan views of portions of other example enclosures 400 are shown. Each of the enclosures 400 comprises one or more features 404 configured to prevent formation of a continuous path of conductive material within the enclosures 400 as described above in FIGS. 2A-2D, 3A, and 3B. As shown in FIG. 4A, a perimeter defined by a first portion 408 and a second portion 412 of the feature 404 is generally “T”-shaped. The second portion 412 is curved to coincide with a curvature of the enclosure 400 in a manner similar to the second portion 340 of FIG. 3B.

As shown in FIG. 4B, the feature 404 comprises a generally triangular or trapezoidal notch 416, recess, etc. An opening 420 of the notch 416 defined in a first (radially inner) surface 424 of the enclosure has a first width and a back (radially outer) wall 428 of the notch 416 has a second width greater than the first width. For example, sidewalls 432 of the notch 416 slope outward relative to (i.e., away from) the opening 420 to the back wall 428. Accordingly, a path from the first surface 424 to the back wall 428 is interrupted.

As shown in FIG. 4C, the feature 404 comprises a first portion 436 and a second portion 440. The first portion 436 comprises vertically-extending rectangular slot similar to the first portion 236 and the first portion 336 shown in FIGS. 2A-2D, 3A, and 3B. The second portion 440 comprises a generally triangular or trapezoidal notch similar to the notch 416 shown in FIG. 4B. The sidewalls 432 slope outward from the first portion 336 to the back wall 428.

As shown in FIG. 4D, the feature 404 comprises a first portion 444 and a second portion 448. The first portion 444 comprises vertically-extending rectangular slot similar to the first portion 236, the first portion 336, and the first portion 436 shown in FIGS. 2A-2D, 3A, 3B, and 4C. The second portion 440 comprises a recess oriented generally perpendicular to the first portion 436. Accordingly, in a plan view, a perimeter of the feature 404 as defined by the first portion 436 and the second portion 440 is generally “L”-shaped.

In each of the examples of the enclosure 400 shown in FIGS. 4A-4D, the features 404 are configured to prevent formation of a continuous path of conductive material around the first surface 424 of the enclosures 400. For example, in each of the features 404, a direct path (e.g., line-of-sight) between the first surface 424 and the back wall 428 of the feature 404. In other words, a width of the feature 404 increases as the feature 404 extends in a radially outward direction. At least one sidewall 432 of the feature 404 does not extend directly (i.e., on a direct path perpendicular to a line 452 normal to the first surface 424) from the first surface 424 to the back wall 428.

While various shapes are described above, other shapes may be used. For example, in some embodiments, the back wall of the feature may not have a width greater than a width of the opening. Instead, a distance between the sidewalls may vary as the feature extends radially outward toward the back wall in a manner that interrupts a direct path from the opening to the back wall. For example, as shown in FIG. 4E, an opening 456 of the feature 404 and a back wall 460 may have generally the same width. However, sidewalls 464 of the opening do not extend directly from the opening 456 to the back wall 460. Accordingly, a conductive path of material formed on the sidewalls 464 is interrupted (e.g., by recesses 468). In other words, the interruption of the conductive path of material may be achieved by varying a distance between the sidewalls 464 as the feature 404 extends in a radial outward direction from the opening 456 to the back wall 460.

Although generally shown as being linear, sidewalls, back walls, etc. of the features described herein may be curved or curvilinear.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An enclosure for a coil in a substrate processing system, the enclosure comprising:
a first body comprised of a dielectric material, wherein the first body comprises a first surface, a second surface, a first edge, and a second edge, and wherein the first surface defines an interior volume of the enclosure configured to contain the coil; and
at least one feature defined in the first surface of the first body, wherein the at least one feature comprises
an opening defined in the first surface, wherein the opening has a first width,
sidewalls extending from the first surface in a direction toward the second surface, and
a back wall located radially outward of the first surface, wherein the sidewalls extend from the first surface to the back wall, and wherein a second distance between the sidewalls varies as the at least one feature extends in a radially outward direction from the opening.

2. The enclosure of claim 1, wherein the back wall has a second width greater than the first width.

3. The enclosure of claim 1, wherein the at least one feature comprises a first portion and a second portion, the first portion comprises a slot defined in the first surface, and the second portion is located radially outward of the first portion and comprises the back wall.

4. The enclosure of claim 3, wherein an outer perimeter of the first portion and the second portion in a plan view is “T”-shaped.

5. The enclosure of claim 3, wherein an outer perimeter of the first portion and the second portion in a plan view is “L”-shaped.

6. The enclosure of claim 1, wherein a shape of the at least one feature in a plan view is one of triangular and trapezoidal.

7. The enclosure of claim 1, further comprising a second body arranged radially outward of the first body.

8. The enclosure of claim 7, wherein the at least one feature comprises a first portion and a second portion, the first portion is formed in the first body, and the second portion is formed in the second body.

9. The enclosure of claim 8, wherein the first portion comprises a slot defined in the first surface, the second portion is located radially outward of the first portion and comprises the back wall, and the back wall has a second width greater than the first width.

10. The enclosure of claim 1, wherein the enclosure is comprised of quartz.

11. The enclosure of claim 1, wherein the at least one feature comprises a plurality of the features.

12. The enclosure of claim 1, wherein the first body is cylindrical.

13. A system comprising the enclosure of claim 1 and further comprising a coil arranged within the enclosure.

14. An enclosure for a coil in a substrate processing system, the enclosure comprising:
a body comprised of a dielectric material, wherein the body comprises a first surface, a second surface located radially outward of the first surface, a first edge, and a second edge;
a first feature defined in the first surface of the body; and
at least one second featured defined in the first surface of the body, wherein each of the first feature and the at least one feature comprises
a first portion, wherein the first portion defines an opening in the first surface and has a first width, and a second portion located radially outward of the first portion, wherein the second portion defines a recess that has a second width greater than the first width.

15. The enclosure of claim 14, wherein sidewalls extend from the first surface to a back wall of the second portion, and wherein the back wall has the second width.

16. The enclosure of claim 14, wherein the first portion and the second portion define an outer perimeter that is “T”-shaped in a plan view.

17. The enclosure of claim 14, wherein the first portion comprises a rectangular slot that extends between the first edge and the second edge on the first surface.

18. The enclosure of claim 14, wherein the dielectric material is quartz.

19. The enclosure of claim 14, wherein the body is cylindrical.

20. An enclosure for a coil in a substrate processing system, the enclosure comprising:
a body comprised of a dielectric material, wherein the body comprises a first surface, a second surface located radially outward of the first surface, a first edge, and a second edge; and
a plurality of features defined in the first surface of the body, wherein each of the plurality of features comprises
a first portion, wherein the first portion comprises a slot that defines an opening in the first surface that extends from the first edge to the second edge, and wherein the first portion has a first width, and
a second portion located radially outward of the first portion, wherein the second portion defines a recess that comprises a back wall located radially outward of the first surface and radially inward of the second surface, and wherein the back wall has a second width greater than the first width.

21. The enclosure of claim 20, wherein the plurality of features is uniformly spaced in a circumferential direction around the first surface.

22. The enclosure of claim 20, wherein the body is cylindrical.
